(19) United States
(12) Patent Application Publication
(10) Pub. No.: US 2012/0247825 A1
(43) Pub. Date: Oct. 4, 2012

(54) PRINTED CIRCUIT BOARD

(75) Inventors: MING WEI, Shenzhen City (CN); CHIA-NAN PAI, New Taipei (TW); NING LI, Shenzhen City (CN); SHOU-KUO HSU, New Taipei (TW)

(73) Assignees: HON HAI PRECISION INDUSTRY CO., LTD., New Taipei (TW); HONG FU JIN PRECISION INDUSTRY (ShenZhen)CO., LTD., Shenzhen City (CN)

(21) Appl. No.: 13/288,144

(22) Filed: Nov. 3, 2011

(30) Foreign Application Priority Data
Mar. 28, 2011 (CN) 201110074784.9

(51) Int. Cl. H05K 1/11

(52) U.S. Cl. 174/266

(57) ABSTRACT

A printed circuit board (PCB) includes a top signal layer, a bottom signal layer, a ground layer, a plurality of vias, and at least two ground vias. Both the top signal layer and the bottom signal layer include at least one protection line. The ground layer is located between the top signal layer and the bottom signal layer. The at least two ground vias extend through the PCB and are located adjacent to the vias on the PCB. The at least two ground vias are electrically connected to the ground layer to conduct noise signals, and the at least two ground vias are electrically connected by the protection lines to insulate noise signals.

### BACKGROUND

1. Technical Field

The disclosure generally relates to printed circuit boards, and more particularly to a printed circuit board used for eliminating coupled noise signals.

2. Description of the Related Art

A multilayer printed circuit board (PCB) is used to mechanically support and electrically connect electronic components using conductive pathways, such as copper traces. The PCB usually defines a plurality of vias, the vias extend through layers of the PCB to allow electrical connections of conductors on different layers. However, arrangement of the vias near conductive pathways, traces, and other vias, may cause coupled noise and mutual interference. To reduce the coupled noise, the distance between vias and the conductive pathways or other vias may be increased, but this will increase the size of the PCB as well.

Therefore, there is room for improvement within the art.

### BRIEF DESCRIPTION OF THE DRAWINGS

Many aspects of a printed circuit board can be better understood with reference to the following drawings. The components in the drawings are not necessarily drawn to scale, the emphasis instead being placed upon clearly illustrating the principles of the printed circuit board. Moreover, in the drawings, like reference numerals designate corresponding parts throughout the several views. Wherever possible, the same reference numbers are used throughout the drawings to refer to the same or like elements of an embodiment.

FIG. 1 is an assembled, cross-sectional view of a printed circuit board including a top signal layer, a first middle signal layer, a second middle signal layer, and a bottom signal layer, according to an embodiment of the disclosure.

FIG. 2 is a schematic wiring layout view of the top signal layer shown in FIG. 1.

FIG. 3 is a schematic wiring layout view of the bottom signal layer shown in FIG. 1.

FIG. 4 is a schematic wiring layout view of one of the middle signal layers shown in FIG. 1.

FIG. 5 is a top plan wiring layout view of the printed circuit board shown in FIG. 1.

FIG. 6 is a partially cut-away view of the printed circuit board along two vias.

FIG. 7 is a schematic wiring layout view of a top signal layer of a printed circuit board, according to a second embodiment of the disclosure.

FIG. 8 is a schematic wiring layout view of a bottom signal layer of the printed circuit board of FIG. 7.

FIG. 9 is a schematic wiring layout view of a middle signal layer of the printed circuit board of FIG. 7.

FIG. 10 is a top plan wiring layout view of the printed circuit board of FIG. 7.

### DETAILED DESCRIPTION

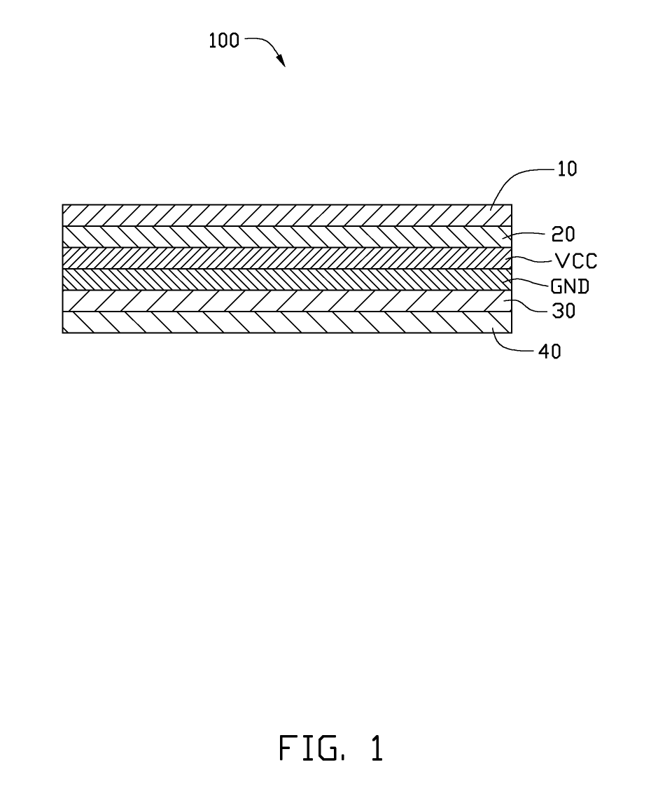

FIG. 1 shows an assembled cross-sectional view of a printed circuit board (PCB) 100 including a top signal layer 10, a first middle signal layer 20, a second middle signal layer 30, and a bottom signal layer 40, according to an embodiment of the disclosure. In this embodiment, the PCB 100 is used to mechanically support and electrically connect electronic components together using conductive pathways such as copper traces. The PCB 100 can be a multilayer board, such as four-layer board or six-layer board, and the six-layer board is taken here as an example to illustrate the PCB 100.

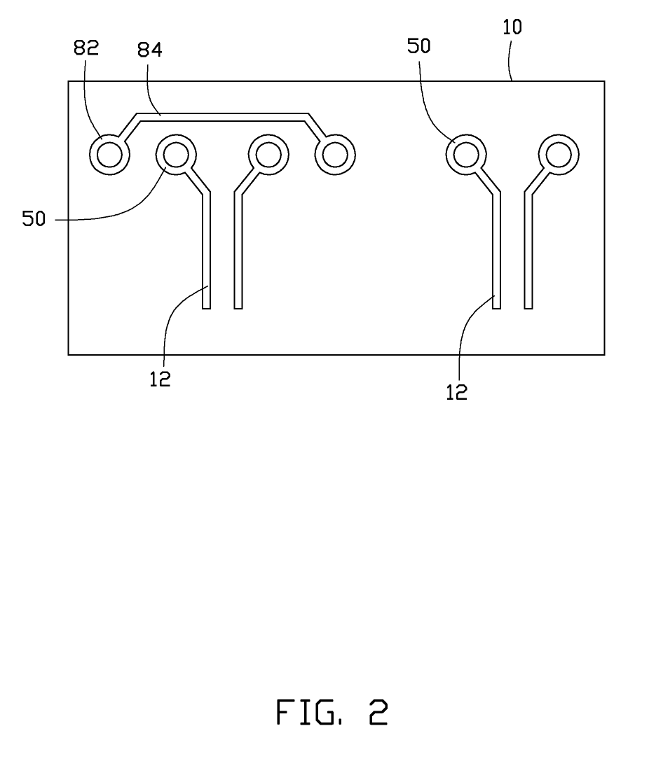

Referring to FIGS. 2-5, the PCB 100 further includes a power source layer VCC and a ground layer GND adjacent to each other. The layer VCC and the layer GND are located between the first middle layer 20 and the second middle layer 30. Thus, the top signal layer 10, the first middle layer 20, the layer VCC, the layer GND, the second middle layer 30 and the bottom signal layer 40 are assembled together in that order.

In this embodiment, at least one group of differential lines 12 is formed on the top signal layer 10. At least one group of differential lines 42 and at least one high-speed signal line 44 are formed on the bottom signal layer 40. The layer VCC is electrically connected to a power supply unit and provides operating power for the PCB 100. The layer GND is ground for electronic components of the PCB 100. The first middle layer 20 and the second middle layer 30 are for additional conductive paths that do not fit on the top layer 10 and the bottom layer 40.

The PCB 100 defines a plurality of vias 50 extending through all or some of the layers of the PCB 100. In this embodiment, the vias 50 are divided into a plurality of groups, each group includes two vias 50 that are electrically connected to two corresponding differential lines 12 in one group of the top signal layer 10. Each of the two vias 50 of one group is electrically connected to a corresponding differential line 42 of the bottom signal layer 40.

In this embodiment, since two differential lines in one group carry and deliver two equal and opposite-phase electrical signals, so when the two equal and opposite-phase electrical signals flow through the two vias 50 that are in the same group, the two vias 50 fail to generate coupled noise and mutual interference.

The PCB 100 further includes at least two ground vias 82 and at least one protection line 84 electrically connected between the corresponding ground via 82 to prevent and insulate noise. In this embodiment, the number of the ground vias 82 is two. The ground vias 82 extend through the PCB 100 and are electrically connected to the layer GND. The centers of the ground vias 82 and the centers of the vias 50 are located on the same line; the two vias 50 of one group are located between the two ground vias 82.

The protection lines 84 are located on the top signal layer 10, the bottom signal layer 40, and the first middle layer 20 and/or the second middle layer 30. In detail, referring to FIG. 2, one of the protection lines 84 is located on the top signal layer 10 and is electrically connected between the ground vias 82. The differential lines 12 are electrically connected to the corresponding vias 50. The protection line 84 and the differential lines 12 are located on the opposite sides of the two vias 50.

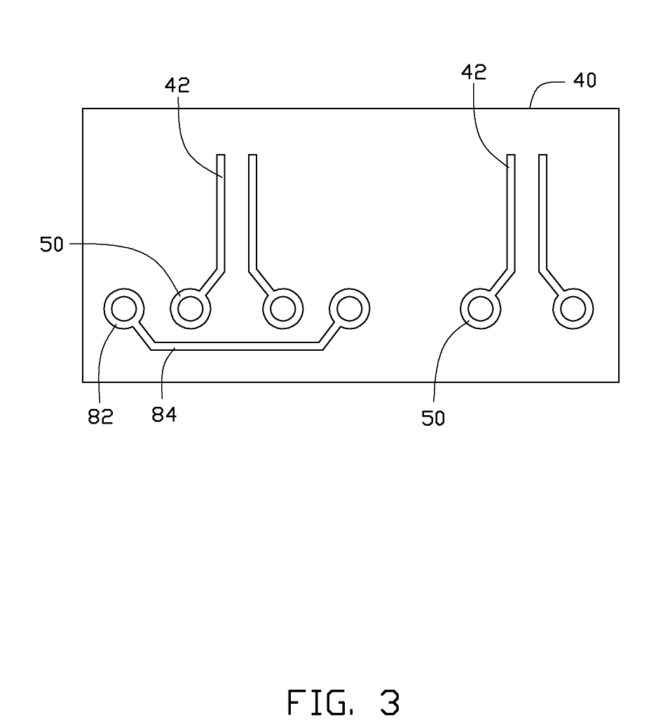

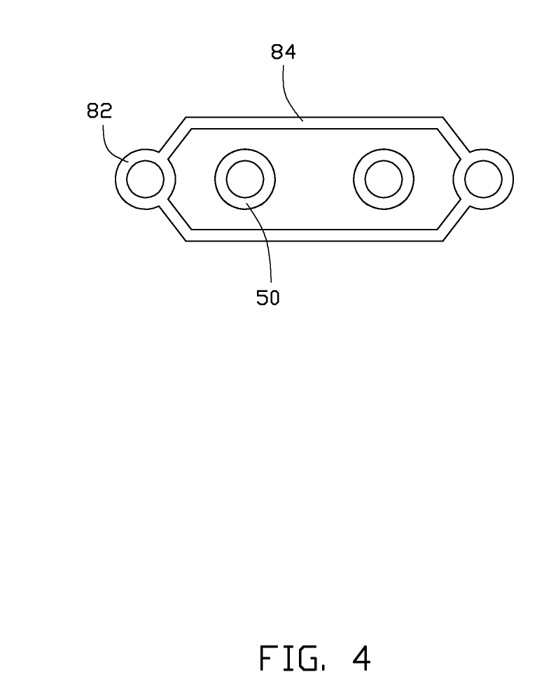

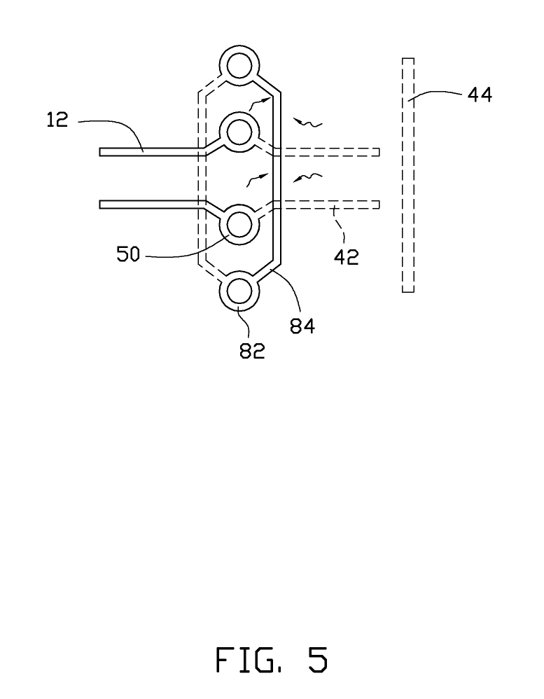

Referring to FIGS. 3 and 5, one of the protection lines 84 is located on the bottom signal layer 10 and is electrically connected between the ground vias 82. The differential lines 42 are electrically connected to the corresponding vias 50. The protection line 84 and the differential lines 42 are located on the opposite sides of the vias 50. The protection line 84 is located between the vias 50 and the high-speed signal line 44 to insulate one line from noise of the other line. Referring to FIG. 4, two protection lines 84 are located on the first middle layer 20 and/or the second middle layer 30, and each of the protection lines 84 is electrically connected between the ground vias 82, forming a closed loop to surround the two vias 50 therein.

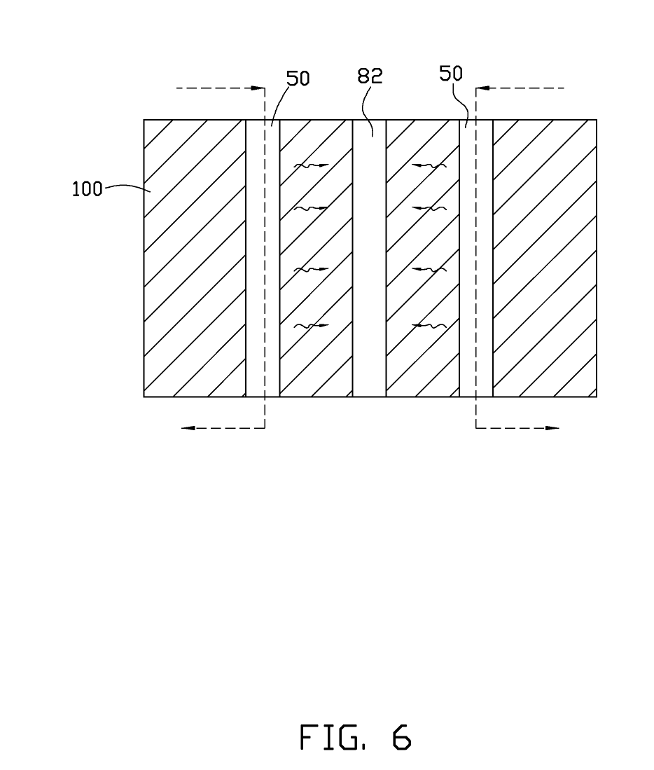

Referring to FIGS. 5 and 6, when the high-speed signal line 44 delivers high-frequency signals, the coupled noise and interference created by the high-speed signal line 44 and the vias 50 are prevented and isolated by the protection line 84, and are further conducted to the layer GND through the protection line 84 and the ground vias 82. In addition, coupled noise and interference between two adjacent vias 50 that are in two different groups are prevented from interfering because any coupled noise is conducted to the layer GND through the ground vias.

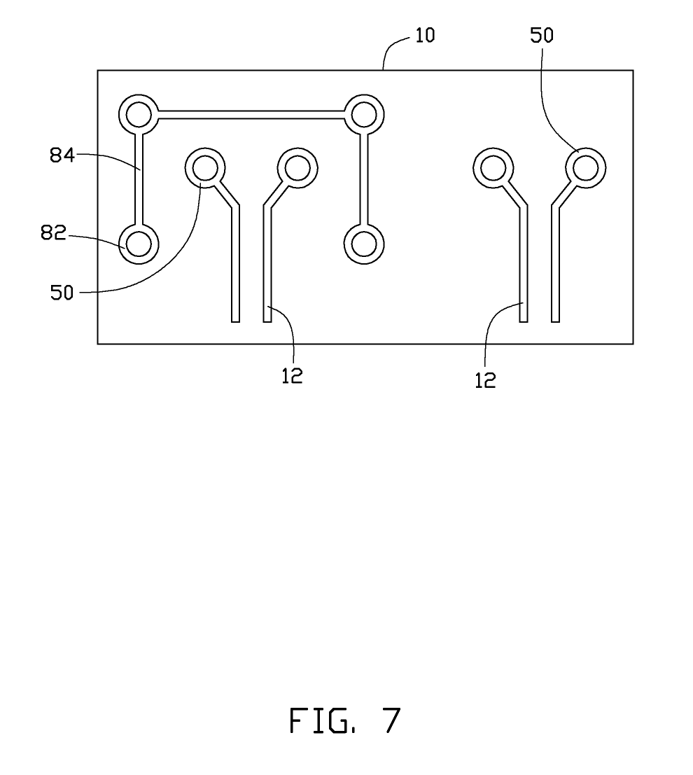

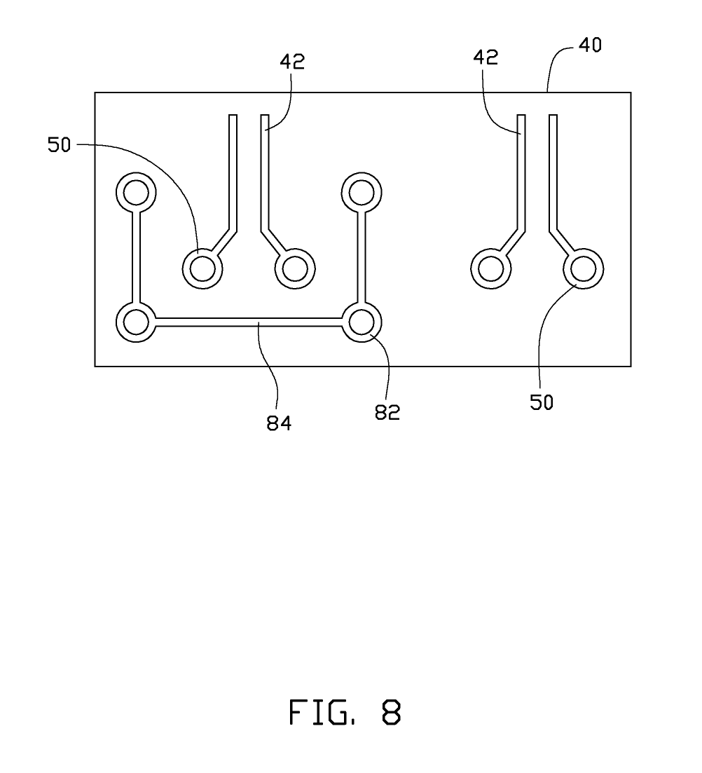

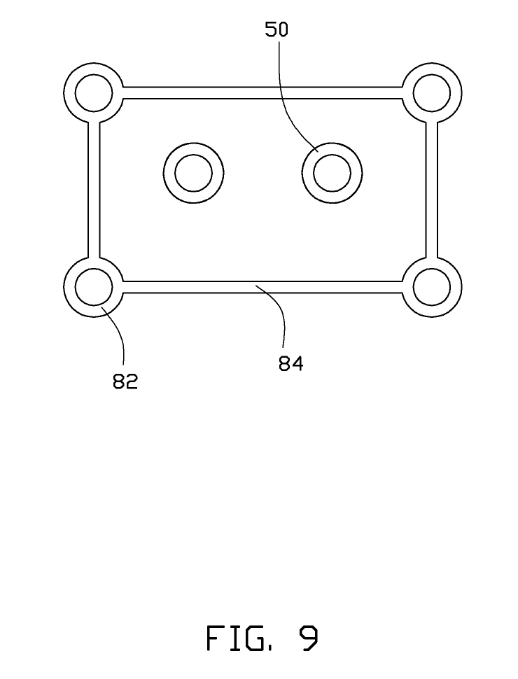

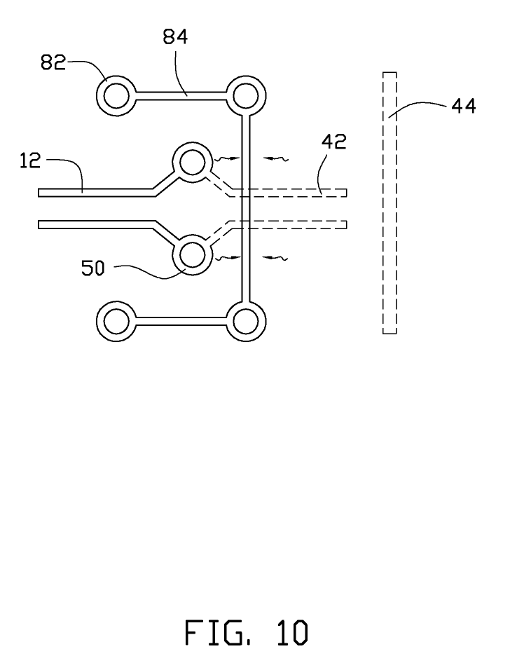

FIGS. 7-10 show a PCB (not shown) according to a second embodiment of the disclosure, which is mostly similar to the PCB 100 of the first embodiment of this disclosure. In this embodiment, the number of the ground vias 82 is four. The four ground vias 82 extend through the PCB and are arranged as a rectangular shape to surround two vias 50 therein. Referring to FIG. 7, the four ground vias 82 are electrically connected in series using three protection lines 84, and the differential lines 12 pass through the interval between two unconnected ground vias 82. Referring to FIGS. 8 and 10, the four ground vias 82 are electrically connected in series using three protection lines 84, the differential lines 42 pass through the interval between two unconnected ground vias 82, and one of the protection lines 84 is located between the vias 50 and the high-speed signal line 44 to prevent and insulate noise. Referring to FIG. 9, four protection lines 84 are located on the first middle layer 20 and/or the second middle layer 30, and are electrically connected end to end, forming a closed loop to surround two vias 50 therein.

In this embodiment, the coupled noise and interference on the bottom signal layer 40 are created by the high-speed signal line 44 and the vias 50, and are prevented and insulated by the protection lines 84, and are further guided to the layer GND through the protection lines 84 and the ground vias 82. In addition, the coupled noise and interference between two adjacent vias 50 in respectively two groups are prevented and insulated by the ground via 84 located between the two adjacent vias 50. The coupled noise is guided to the layer GND through the protection lines 84 and the ground vias 82.

In other embodiment, each group of the vias can include one, three, four or five vias 50, but not limited to two. In addition, the number of the ground vias 82 can be adjustably increased, such as six or eight, but not limited to two or four.

Moreover, the PCB can be a four-layer board, which omit the first middle layer 20 and the second middle layer 30. Thus, the protection lines 84 can be located on the ground layer GND.

In summary, in the PCB of this disclosure, the ground vias 82 are located and arranged adjacent to the corresponding vias 50, and the ground vias 82 are electrically connected using the protection lines 84. Thus, the coupled noise and the interference between the two adjacent vias 50 are prevented and isolated by the ground vias 82 and the protection lines 84. In addition, the protection lines 84 are located between the high-speed signal line 44 and the via 82. Thus, the coupled noise and interference between the vias 50 and the high-speed signal line 44 are prevented and insulated by the protection line 84, but not increasing the size of the PCB.

In the present specification and claims, the word “a” or “an” preceding an element does not exclude the presence of a plurality of such elements. Further, the word “comprising” does not exclude the presence of other elements or steps than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A printed circuit board (PCB), comprising:
a top signal layer comprising at least one protection line;
a bottom signal layer comprising at least one protection line;
a ground layer located between the top signal layer and the bottom signal layer;
a plurality of vias extending through the PCB; and
at least two ground vias, wherein the at least two ground vias extend through the PCB and are located adjacent to the vias on the PCB, the at least two ground vias are electrically connected to the ground layer to conduct noise signals, and the at least two ground vias are electrically connected by the protection lines to insulate noise signals.

2. The PCB as claimed in claim 1, wherein at least one group of differential lines is formed on the top signal layer, and at least one group of differential lines and at least one high-speed signal line are formed on the bottom signal layer, and the ground layer is ground for electronic components of the PCB.

3. The PCB as claimed in claim 2, further comprising a first middle signal layer and a second middle signal layer, wherein the first middle signal layer and the second middle signal layer are located between the top signal layer and the bottom signal layer, and are for additional conductive paths that do not fit on the top signal layer and the bottom signal layer.

4. The PCB as claimed in claim 3, further comprising a power source layer adjacent to the ground layer, wherein the power source layer and the ground layer are located between the first middle signal layer and the second middle signal layer, the power source layer is electrically connected to a power supply unit and provide operating power for the PCB, and the top signal layer, the first middle signal layer, the power source layer, the ground layer, the second middle signal layer and the bottom signal layer are assembled together in that order.

5. The PCB as claimed in claim 2, wherein the vias are divided into a plurality of groups, and each group comprises two vias that are electrically connected to two corresponding differential lines in one group of the top signal layer, each of the vias of the group is electrically connected to a corresponding differential line of the bottom signal layer.

6. The PCB as claimed in claim 2, wherein one of the protection lines is located on the top signal layer and electrically connected between the group vias, the differential lines are electrically connected to the corresponding vias, and the protection line and the differential lines are located on the opposite sides of the two vias.

7. The PCB as claimed in claim 2, wherein one of the protection line is located on the bottom signal layer and is electrically connected between the ground vias, the differential lines are electrically connected to the corresponding vias, the protection line and the differential lines are located on the opposite sides of the vias, and the protection line is located between the vias and the high-speed signal line to prevent and insulate noise.

8. The PCB as claimed in claim 3, wherein two protection lines are located on the first middle signal layer and/or the second middle signal layer, and each of the protection lines is electrically connected between the ground vias to form a closed loop to surround the two vias.

9. The PCB as claimed in claim 2, wherein the coupled noise and interference created by the high-speed signal line and the vias are insulated by the protection line, and are conducted to the ground layer through the protection line and the ground vias, and the coupled noise and interference between two adjacent vias that are in two different groups are prevented from interfering because any coupled noise is conducted to the ground layer through the ground vias.

10. The PCB as claimed in claim 1, wherein the PCB comprises four ground vias extending through the PCB, the four ground vias are electrically connected in series using three protection lines on the top signal layer and the bottom signal layer, and the four protection lines are located on the first middle signal layer and/or the second middle signal layer, and are electrically connected end to end to form a closed loop to surround two vias.

11. A printed circuit board (PCB), comprising:
a top signal layer configured for supporting electronic components and signal lines;
a bottom signal layer adjacent to the top signal layer and configured for supporting at least one high-speed signal lines;
a ground layer located between the top signal layer and the bottom signal layer;
a plurality of protection lines located on the top signal layer and the bottom signal layer;
a plurality of vias extending through the PCB; and
a plurality of ground vias extending through the PCB, wherein the plurality of ground vias are located adjacent to the plurality of the vias and are electrically connected by the corresponding protection lines, the plurality of ground vias prevent and insulate coupled noise between the vias, and the plurality of protection lines prevent and insulate coupled noise between the vias and/or the plurality of vias and the high-speed signal lines.

12. The PCB as claimed in claim 11, wherein at least one group of differential lines is formed on the top signal layer, at least one group of differential lines is formed on the bottom signal layer, and the ground layer is ground for electronic components of PCB.

13. The PCB as claimed in claim 12, further comprising a first middle signal layer and a second middle signal layer, wherein the first middle signal layer and the second middle signal layer are located between the top signal layer and the bottom signal layer, and are for additional conductive paths that do not fit on the top signal layer and the bottom signal layer.

14. The PCB as claimed in claim 13, further comprising a power source layer adjacent to the ground layer, wherein the power source layer and the ground layer are located between the first middle signal layer and the second middle signal layer, the power source layer is electrically connected to a power supply unit and provide operating power for the PCB, and the top signal layer, the first middle signal layer, the power source layer, the ground layer, the second middle signal layer and the bottom signal layer are assembled together in that order.

15. The PCB as claimed in claim 12, wherein the vias are divided into a plurality of groups, and each group comprises two vias that are electrically connected to two corresponding differential lines in one group of the top signal layer, each of the vias of the group is electrically connected to a corresponding differential line of the bottom signal layer.

16. The PCB as claimed in claim 12, wherein one of the protection lines is located on the top signal layer and electrically connected between the group vias, the differential lines are electrically connected to the corresponding vias, and the protection line and the differential lines are located on the opposite sides of the two vias.

17. The PCB as claimed in claim 12, wherein one of the protection line is located on the bottom signal layer and is electrically connected between the ground vias, the differential lines are electrically connected to the corresponding vias, the protection line and the differential lines are located on the opposite sides of the vias, and the protection line is located between the vias and the high-speed signal line to prevent and insulate noise.

18. The PCB as claimed in claim 13, wherein two protection lines are located on the first middle signal layer and/or the second middle signal layer, and each of the protection lines is electrically connected between the ground vias to form a closed loop to surround the two vias.

19. The PCB as claimed in claim 12, wherein the coupled noise and interference created by the high-speed signal line and the vias are insulated by the protection line, and are conducted to the ground layer through the protection line and the ground vias, and the coupled noise and interference between two adjacent vias that are in two different groups are prevented from interfering because any coupled noise is conducted to the ground layer through the ground vias.

20. The PCB as claimed in claim 11, wherein the PCB comprises four ground vias extending through the PCB, the four ground vias are electrically connected in series using three protection lines on the top signal layer and the bottom signal layer, and the four protection lines are located on the first middle signal layer and/or the second middle signal layer, and are electrically connected end to end to form a closed loop to surround two vias.
